(19) United States
(12) Patent Application Publication
(10) Pub. No.: US 2011/0204439 A1
(43) Pub. Date: Aug. 25, 2011

(54) SEMICONDUCTOR DEVICE

(75) Inventor: Yusuke KAWAGUCHI, Kanagawa-ken (JP)

(73) Assignee: Kabushiki Kaisha Toshiba, Tokyo (JP)

(21) Appl. No.: 13/031,564

(22) Filed: Feb. 21, 2011

(30) Foreign Application Priority Data
Feb. 24, 2010 (JP) P2010-038324

(51) Int. Cl. H01L 29/78

(52) U.S. Cl. 257/331; 257/E29.262

(57) ABSTRACT

Embodiments provide a semiconductor device including an N-type semiconductor layer 2, insulating films 4a and 4b provided on inner surfaces of trenches 3 formed on a surface of the semiconductor layer 2, first electrodes 6 each provided at a bottom part of the trench 3 and facing the semiconductor layer 2 with the insulating film 4a interposed therebetween, and second electrodes 7 each provided inside the trench 3 and above the first electrode 6. A work function of a member constituting the first electrodes 6 is smaller than a work function of a member constituting the second electrodes 7.

### CROSS-REFERENCE TO RELATED APPLICATION

This application is based upon and claims the benefit of priority from Japanese Patent Application No. P2010-38324, filed on Feb. 24, 2010; the entire contents of which are incorporated herein by reference.

### FIELD

The present invention relates to a semiconductor device, and more specifically to a power control semiconductor device including a trench gate, for example.

### BACKGROUND

Power control semiconductor elements are used for power management of portable instruments such as notebook personal computers in addition to conventional large-current and high-voltage applications. Accordingly, there is a demand for semiconductor elements which can be driven at low voltage and have low on-resistance, and which further have small gate-drain capacitance in order to reduce a switching loss.

Meanwhile, an element structure including a trench gate is effective for reducing the on-resistance, and there is known a technique to reduce channel resistance by narrowing down a trench pitch. However, in the case of a MOSFET, for example, it may be difficult to control a threshold voltage if an interval between the trenches is too small because such an arrangement is likely to reduce an amount of an impurity contained in a channel region. In this regard, when the threshold voltage is stabilized by increasing concentration of a base layer of the MOSFET, there is a problem that a reduction effect corresponding to size reduction cannot be achieved because of an increase in channel resistance.

To solve the problem described above, a study has been conducted on a semiconductor device having a device structure of a so-called SIT (static induction transistor) type that does not include the base layer. Patent Document 1 discloses a semiconductor device having a cutoff performance stabilized by increasing a work function difference between a channel region and a gate electrode. However, there is still room for improvement to reduce the channel resistance.

### BRIEF DESCRIPTION OF THE DRAWINGS

FIG. 1 is a schematic diagram showing a cross section of a semiconductor device according to a first embodiment.

FIGS. 2A and 2B are schematic diagrams showing band structures between an N-type semiconductor layer and a trench gate.

FIGS. 3A and 3B are schematic diagrams showing band structures when a semiconductor material is used as a gate electrode.

FIGS. 4A and 4B are schematic diagrams showing band structures between a P-type semiconductor layer and a trench gate.

FIG. 5 is a schematic diagram showing a cross section of a semiconductor device according to a modified example of the first embodiment.

FIG. 6 is a schematic diagram showing a cross section of a semiconductor device according to a second embodiment.

FIGS. 7A and 7B are schematic diagrams showing a band structure according to the second embodiment.

FIG. 8 is a schematic diagram showing a cross section of a semiconductor device according to a modified example of the second embodiment.

FIG. 9 is a schematic diagram showing a cross section of a semiconductor device according to a third embodiment.

FIG. 10 is a schematic diagram showing a cross section of a semiconductor device according to a modified example of the third embodiment.

FIG. 11 is a schematic diagram showing a cross section of a semiconductor device according to a fourth embodiment.

FIG. 12 is a schematic diagram showing a cross section of a semiconductor device according to a modified example of the fourth embodiment.

### DETAILED DESCRIPTION

An aspect of the present invention provides a semiconductor device including: an N-type semiconductor layer; an insulating film provided on an inner surface of a trench formed on a surface of the semiconductor layer; a first electrode provided at a bottom portion of the trench and facing the semiconductor layer through the insulating film; and a second electrode provided inside the trench above the first electrode. In the semiconductor device, a work function of a member constituting the first electrode is smaller than a work function of a member constituting the second electrode.

Embodiments of the present invention will be described below with reference to the drawings. In the following embodiments, the same components in the drawings are designated by the same reference numerals and detailed description thereof will be omitted as appropriate, but different components will be described as appropriate.

### First Embodiment

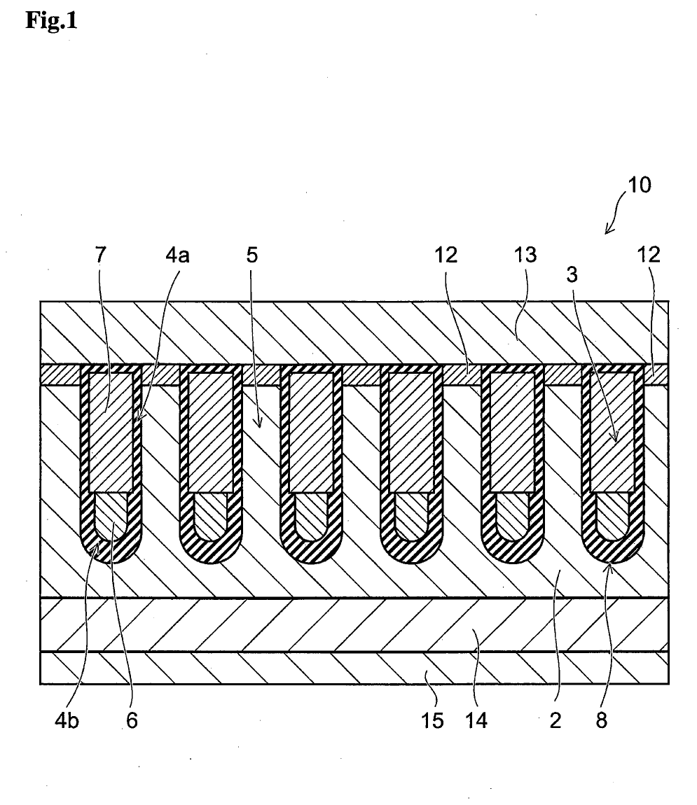

FIG. 1 is a schematic diagram showing a cross section of a semiconductor device 10 according to a first embodiment. The semiconductor device 10 is a power control semiconductor device configured to control a current flowing between a source electrode 13 and a drain electrode 15 by way of gate electrodes 6 and 7 provided inside trenches 3 formed on a surface of an N-type semiconductor layer 2.

Insulating films functioning as gate insulating films 4a and 4b are provided on inner surfaces of the trenches 3 formed on the surface of the semiconductor layer 2. In addition, the gate electrodes 6 serving as first electrodes are provided at bottom portions of the trenches 3 while facing the semiconductor layer 2 through the gate insulating films 4b. Moreover, the gate electrodes 7 serving as second electrodes are provided inside the trenches 3 above the gate electrodes 6. The gate electrodes 7 face channel regions 5 which are part of the semiconductor layer 2 through the gate insulating films 4a. A member constituting the gate electrodes 6 includes a material having a work function smaller than that of a member constituting the gate electrodes 7.

A source region 12 doped with a higher concentration of an N-type impurity than the semiconductor layer 2 is provided on a surface of the semiconductor layer 2 in positions sandwiched between the gate electrodes 7 in order to reduce contact resistance between the semiconductor layer 2 and the source electrode 13. In addition, a drain layer 14 is provided between a backside of the semiconductor layer 2 and the drain electrode 15. The drain region 14 is also doped with a higher concentration of the N-type impurity than the semiconductor layer 2 in order to reduce contact resistance between the semiconductor layer 2 and the drain electrode 15.

Next, operations of the semiconductor device 10 will be described. When the source electrode 13 is grounded and a positive voltage is applied to the drain electrode 15, for example, the semiconductor device 10 is set to an on-state in which a drain current flows from the drain electrode 15 to the gate electrode 13 through the channel regions 5 between the adjacent gate electrodes 7.

On the other hand, when the gate electrodes 7 are biased at a negative potential relative to the channel regions 5, depletion regions are formed in the channel regions 5 so as to extend from interfaces between the gate insulating films 4a and the channel regions 5, the gate insulating films 4a insulating the channel regions 5 from the gate electrodes 7. The depletion regions extend from both of the gate electrodes 7 sandwiching each of the channel regions 5, and the drain current is cut off when the channel regions 5 are entirely depleted, thereby setting the semiconductor device 10 to an off-state.

Specifically, the semiconductor device 10 can control the on-state and the off-state by changing an electric potential of the gate electrodes 7 so as to switch the drain current that flows between the drain electrode 15 and the source electrode 13.

To form the trench gates shown in FIG. 1, the gate insulating films 4b are formed on the inner surfaces of the trenches 3 formed on the surface of the semiconductor layer 2 and then the member constituting the gate electrodes 6 is firstly buried into the trenches 3, for example. Further, the gate electrodes 6 are formed at the bottom portions of the trenches 3 by etching back the buried member. Subsequently, the member constituting the gate electrodes 7 is buried into spaces formed above the gate electrodes 6.

Additionally, in etching back the member constituting the gate electrodes 6, the gate insulating films 4a can be made thinner than the gate insulating films 4b by etching the insulating films formed on the inner surfaces of the trenches 3, for example. Specifically, it is possible to ensure the film thickness of the gate insulating films 4b for maintaining high gate-drain dielectric breakdown strength and to form the film thickness of the gate insulating films 4a into an appropriate thickness for controlling the depletion regions formed in the channel regions 5.

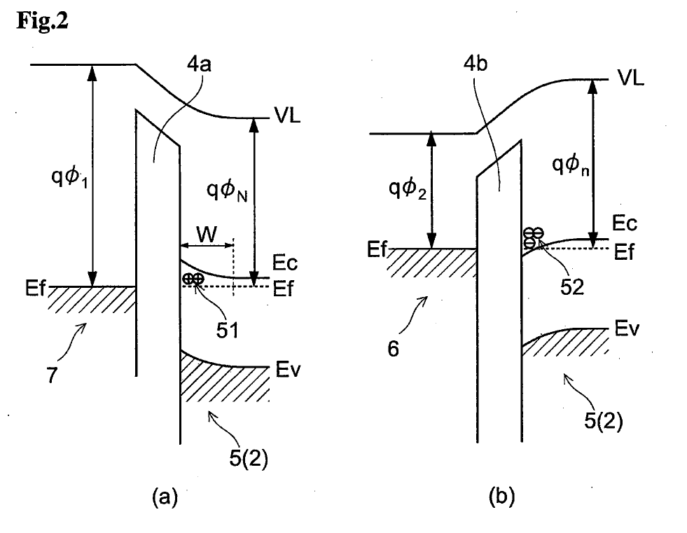

Next, potential differences between the channel region 5 and the gate electrodes 6 and 7 will be described with reference to FIG. 2A to FIG. 4B. It is desirable that a power control semiconductor device be provided with a normally-off characteristic. Accordingly, FIG. 2A to FIG. 4B illustrate band structures of the trench gates in the case where a gate voltage is 0 V. As shown in the drawings, a work function is an energy difference between a Fermi level E_{F} and a vacuum level VL.

FIG. 2A schematically shows an example of the band structure in which the channel region 5 being part of the N-type semiconductor layer 2 faces the gate electrode 7 with the gate insulating film 4a interposed therebetween. In the example shown in FIG. 2A, the gate electrode 7 is formed by use of the material having a work function qφ₁ which is greater than a work function qφ_{N} of the semiconductor layer 2. As shown in this drawing, a potential difference is generated between the gate electrode 7 and the channel region 5 due to the energy difference between the work functions qφ₁ and qφ_{N}. Accordingly, a conduction band E_{C} and a valence band E_{V} of the semiconductor layer 2 are bent upward on an interface between the gate insulating film 4a and the channel region 5, whereby a depletion region W is formed by an ionized N-type impurity 51 inside the channel region 5.

The channel region 5 is entirely depleted if the width of the channel region 5 sandwiched between two gate electrodes 7 is narrower than 2W. Hence it is possible to establish the off-state by cutting off the drain current. Additionally, the depletion region W extends more easily if there is a larger difference in the work function between the semiconductor layer 2 and the gate electrode 7.

On the other hand, FIG. 2B shows an example of the band structure in which the channel region 5 faces the gate electrode 6 with the gate insulating film 4b interposed therebetween. In FIG. 2B, a work function qφ₂ of the material constituting the gate electrode 6 is smaller than the work function qφ_{N} of the semiconductor layer 2. Accordingly, as shown in FIG. 2B, the conduction band E_{C} and the valence band E_{V} of the semiconductor layer 2 are bent downward on an interface between the channel region 5 and the gate insulating film 4b, whereby an electron accumulation region 52 is formed.

For example, when the gate electrode 6 is provided by using the same material as the gate electrode 7, the depletion region W is formed on the entire interface between the semiconductor layer 2 and the gate insulating films 4a, 4B along the inner surface of the trench 3, whereby the entire channel region 5 sandwiched between the adjacent gate electrodes 6 and 7 is depleted.

Meanwhile, even when the difference in the work function between the gate electrode 6 and the semiconductor layer 2 is not large enough for forming the accumulation region 52 on the interface between the gate insulating film 4b and the channel region 5, the width of the portion of the depletion region facing the gate electrode 6 can be made narrower than that of the channel region 5 facing the gate electrode 7 by setting the work function of the member constituting the gate electrode 6 smaller than the work function of the member constituting the gate electrode 7. Moreover, the electron accumulation region 52 can be formed on the interface between the gate insulating film 4b and the semiconductor layer 2 as well as the channel region 5, more easily than on the interface between the gate insulating film 4a and the channel region 5, in the case of applying a gate voltage.

A current path expands when the depletion region in the channel region 5 becomes narrow. Meanwhile, the accumulation region 52 has smaller resistance than that of the interface on which no electrons accumulate. Therefore, by setting the work function qφ₂ of the material of the gate electrode 6 smaller than the work function qφ₁ of the material of the gate electrode 7, the resistance of the channel region 5 can be reduced more than the case of forming both of the gate electrodes by using materials having the same work function.

For example, the gate electrode 6 can be provided at the bottom portion of the trench 3 while a width of the gate electrode 7 in a depth direction from the surface of the semiconductor layer 2 toward the bottom portion of the trench 3 are defined as a minimum width which can cut off the drain current. Moreover, by setting the work function qφ₂ of the material of the gate electrode 6 smaller than the work function qφ₁ of the material of the gate electrode 7, it is possible to reduce the resistance of the channel region 5 and thereby to reduce on-resistance.

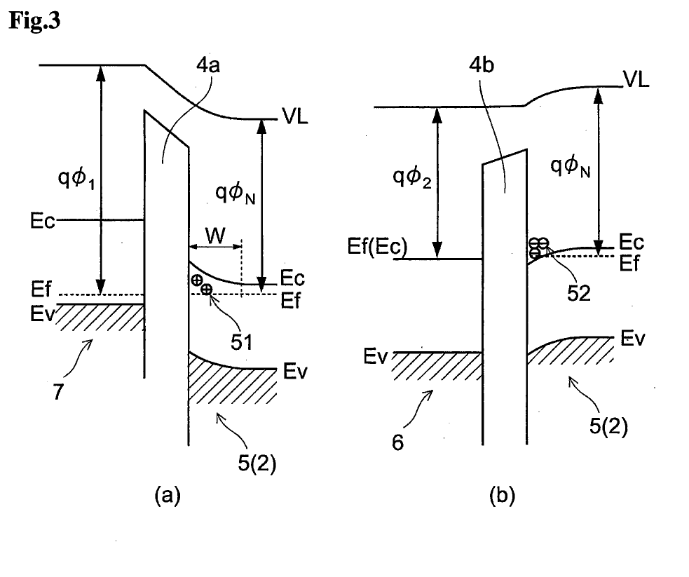

FIGS. 3A and 3B are schematic diagrams showing examples of the band structures when the gate electrodes 6 and 7 are made of semiconductor materials. FIG. 3A shows the band structure between the gate electrode 7 and the channel region 5. In addition, FIG. 3B shows the band structure between the gate electrode 6 and the channel region 5.

In the example shown in FIG. 3A, a semiconductor having P-type conductivity is used as the material of the gate electrode 7. For example, it is possible to use polysilicon doped with a P-type impurity. When the semiconductor layer 2 is an N-type silicon layer, a potential difference around 1 V is generated between the gate electrode 7 and the channel region 5. Accordingly, the conduction band E_{C} and the valence band E_{V} of the channel region 5 of the semiconductor layer 2 are bent upward on the interface between the gate insulating film 4a and the channel region 5 as shown in FIG. 3A, thereby forming the depletion region W.

On the other hand, in the example shown in FIG. 3B, a semiconductor having N-type conductivity is used as the material of the gate electrode 6. For example, it is possible to use polysilicon doped with an N-type impurity. The work function of the N-type polysilicon doped with the N-type impurity is smaller than the work function of the N-type silicon layer constituting the semiconductor layer 2. Accordingly, the electron accumulation region 52 is formed on the interface between the gate insulating film 4b and the channel region 5 as shown in FIG. 3B.

Therefore, the work function qφ₂ of the gate electrode 6 can be set smaller than the work function qφ₁ of the gate electrode 7 in the example shown in FIGS. 3A and 3B. In this way, it is possible to make the resistance of the channel region 5 smaller and thereby to reduce the on-resistance.

Meanwhile, P-type silicon carbide (SiC) can be employed as the semiconductor material to be used for the gate electrode 7, for example. In the meantime, N-type SiC or polysilicon can be employed as the material of the gate electrode 6.

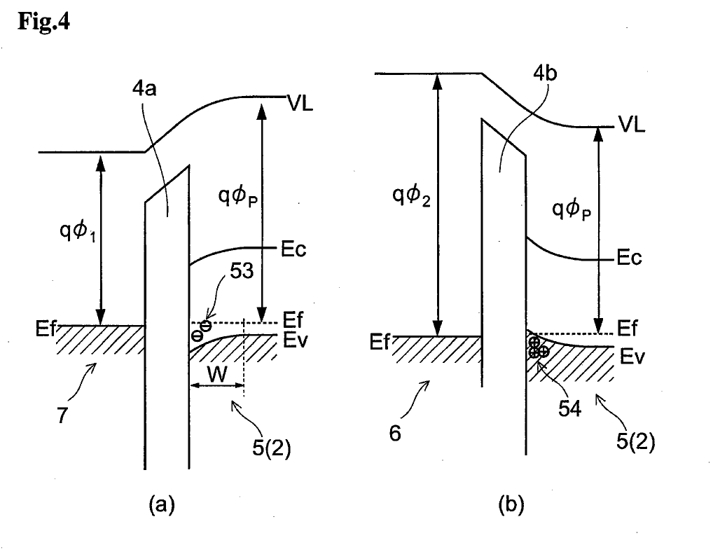

FIGS. 4A and 4B are schematic diagrams showing band structures between a P-type semiconductor layer 2 and a trench gate. FIG. 4A shows the band structure between the gate electrode 7 and the channel region 5 being part of the P-type semiconductor layer 2. In addition, FIG. 4B shows the band structure between the gate electrode 6 and the channel region 5.

In the example shown in FIG. 4A, the gate electrode 7 is formed by use of the material having the work function qφ₁ which is smaller than a work function qφ_{P} of the semiconductor layer 2. As shown in the drawing, a potential difference is generated between the gate electrode 7 and the channel region 5 due to the energy difference between the work functions qφ_{P} and qφ₁. Accordingly, the conduction band E_{C} and the valence band E_{V} of the semiconductor layer 2 are bent downward on an interface between the gate insulating film 4a and the semiconductor layer 2, whereby a depletion region W is formed by an ionized P-type impurity 53 inside the semiconductor layer 2.

On the other hand, in the example shown in FIG. 4B, the work function qφ₂ of the material constituting the gate electrode 6 is greater than the work function qφ_{P} of the semiconductor layer 2. Accordingly, as shown in FIG. 4B, the conduction band E_{C} and the valence band E_{V} of the semiconductor layer 2 are bent upward on an interface between the channel region 5 and the gate insulating film 4b, whereby a hole accumulation region 54 is formed.

In this way, the work function qφ₂ of the material of the gate electrode 6 is set greater than the work function qφ₁ in of the material of the gate electrode 7 when the semiconductor layer 2 has the P-type conductivity. Hence it is possible to reduce the resistance of the channel region 5. Here, SiC or polysilicon having the N-type conductivity can be employed as the material of the gate electrode 7, for example. In the meantime, SiC having the P-type conductivity can be employed as the material of the gate electrode 6.

As described above, by setting the work functions each representing the potential difference between the Fermi level E_{F} and the vacuum level VL to satisfy the predetermined magnitude relation, it is possible to reduce the on-resistance by forming a carrier accumulation region on the interface between the semiconductor layer 2 facing the gate electrode 6 and the gate insulating film 4b, and thereby to stabilize control of the channel region in the gate electrode 7.

In addition, it is possible to narrow down the width of the depletion region that extends in the channel region 5 facing the gate electrode 6 by setting the difference in the work function between the material constituting the gate electrode 6 and the material constituting the gate electrode 7 even though the difference is not large enough for forming the accumulation region on the interface facing the gate electrode 6. Hence it is possible to obtain the effect to reduce the on-resistance.

In the example shown in FIGS. 3A and 3B, the conduction band E_{C} and the valence band E_{V} are illustrated on the gate electrode side for the sake of convenience in order to depict the P-type semiconductor and the N-type semiconductor. However, the operation and effect of this embodiment can be explained only by use of the energy difference between the Fermi level E_{F} and the vacuum level VL, i.e., the work function. In other words, it is apparent that the configurations shown in FIGS. 2A, 2B and FIGS. 4A, 4B can be realized not only by use of the metallic materials but also by use of the semiconductor materials.

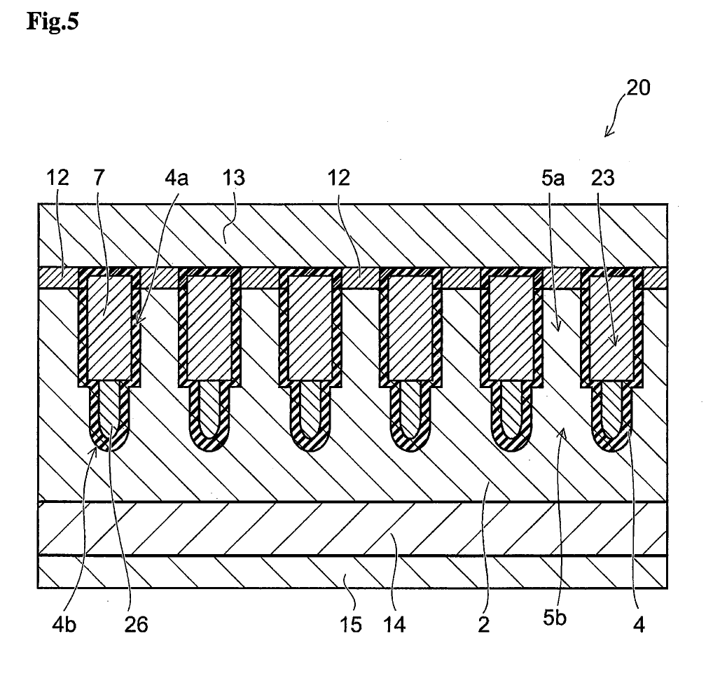

FIG. 5 is a schematic diagram showing a cross section of a semiconductor device 20 according to a modified example of the first embodiment. The semiconductor device 20 includes gate electrodes 7 and 26 which are provided inside trenches 23 formed on a surface of an N-type semiconductor layer 2.

A bottom portion of each of the trenches 23 provided with the gate electrode 26 is formed into a narrower width than a width of a portion where the gate electrode 7 is provided. In this way, a width in an arrangement direction of a channel region 5b sandwiched between two gate electrodes 26 adjacent to each other in an arrangement direction of the trenches 23 is wider than a width in the arrangement direction of a channel region 5a sandwiched between two adjacent gate electrodes 7. Specifically, the channel region 5a configured to cut off the drain current flowing between a drain electrode 15 and a source electrode 13 is set to the same width as that in the semiconductor device 10 shown in FIG. 1 so as to maintain a characteristic to cut off the drain current. Meanwhile, the channel resistance is reduced by increasing the width of the channel region 5b close to the drain electrode 15. Thus, it is possible to make on-resistance smaller than that in the semiconductor device 10 shown in FIG. 1.

In this modified example as well, when the semiconductor layer 2 has the N-type conductivity, the material constituting the gate electrode 26 has the work function smaller than the work function of the material constituting the gate electrode 7. On the other hand, when the semiconductor layer 2 has the P-type conductivity, the work function of the material constituting the gate electrode 26 is set greater than the work function of the material constituting the gate electrode 7.

In addition, the trench gates shown in FIG. 5 can be formed in the following manner: the member constituting the gate electrodes 26 is etched back to form the gate electrodes 26 at the bottom portions of the trenches 23, and then inner surfaces at upper parts of the trenches 23 are etched to expand. In this case, the gate insulating films 4a to be formed on the expanded inner surfaces at the upper parts of the trenches 23 can be formed thinner than the gate insulating films 4b to be formed between the gate electrodes 26 and the semiconductor layer 2.

### Second Embodiment

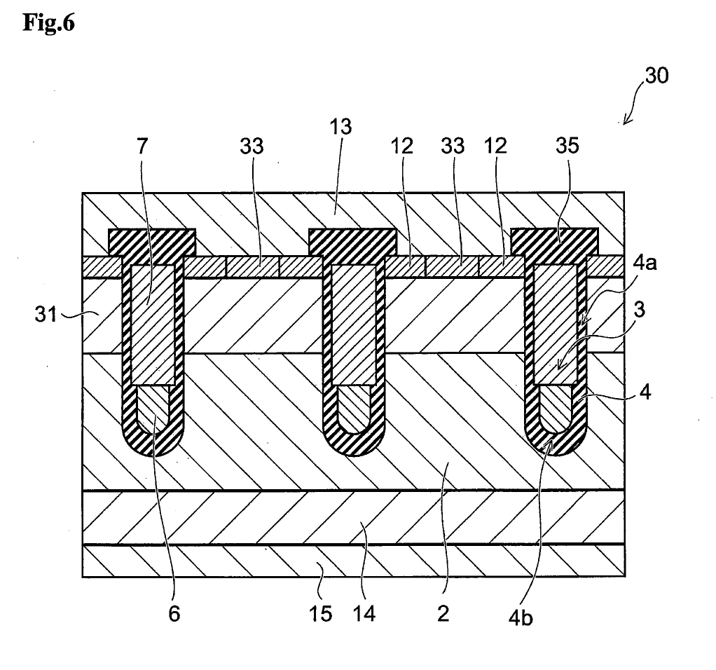

FIG. 6 is a schematic diagram showing a cross section of a semiconductor device 30 according to a second embodiment. The semiconductor device 30 is a MOSFET including a base region 31 provided on a surface of a semiconductor layer 2.

When the semiconductor layer 2 is made of the N-type semiconductor, for example, the base region 31 has the P-type conductivity and P-type contact regions 33, each of which is formed so as to be sandwiched between an N-type source region 12 and another N-type source region 12, are provided on a surface of the base region 31. Further, a source electrode 13 is provided so as to be electrically connected to the N-type source regions 12 and the P-type contact regions 33.

Meanwhile, gate electrodes 6 and gate electrodes 7 are provided inside trenches 3 formed on the surface of the semiconductor layer 2. Each gate electrode 6 provided at a bottom portion of the trench 3 faces the semiconductor layer 2 with a gate insulating film 4b interposed therebetween. In the meantime, each gate electrode 7 provided above the gate electrode 6 faces the base region 31 with a gate insulating film 4a interposed therebetween. Moreover, an interlayer insulating film 35 is provided on an upper part of each trench 3 so as to insulate the gate electrode 7 from the source electrode 13.

In this embodiment as well, when the semiconductor layer 2 has the N-type conductivity, it is possible to use a member, which has a smaller work function than that of a member constituting the gate electrode 7, as a member constituting the gate electrode 6. On the other hand, when the semiconductor layer 2 has the P-type conductivity, the work function of the member constituting the gate electrode 6 is set greater than the work function of the member constituting the gate electrode 7.

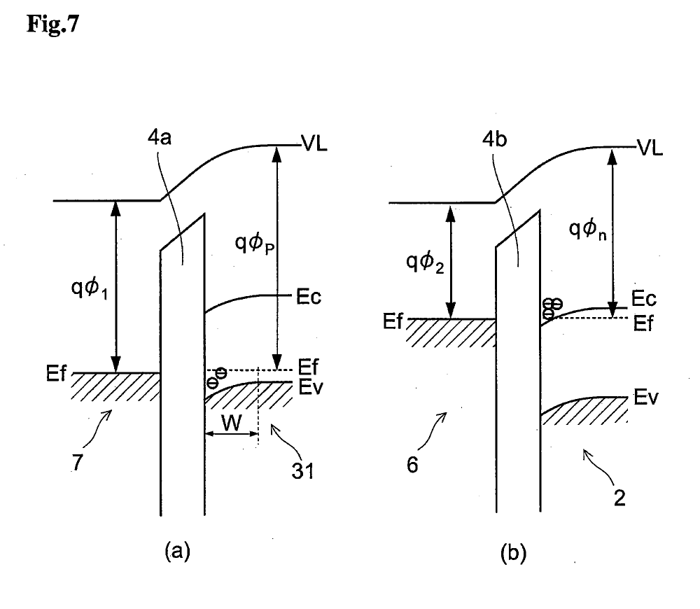

FIGS. 7A and 7B are schematic diagrams showing examples of band structures of trench gates according to this embodiment. In this case, the semiconductor layer 2 has the N-type conductivity. FIG. 7A shows the band structure between the gate electrode 7 and the base region 31 with the gate insulating film 4a interposed therebetween. Meanwhile, FIG. 7B shows the band structure between the gate electrode 6 and the semiconductor layer 2 with the gate insulating film 4b interposed therebetween.

As shown in FIG. 7A, a potential difference is generated between the gate electrode 7 and the base region 31 due to an energy difference between a work function qφ₁ of the gate electrode 7 and a work function qφ_{P} of the base region 31, whereby a conduction band E_{C} and a valence band E_{V} are bent downward. Accordingly, it is possible to form a depletion region W on an interface between the gate insulating film 4a and the base region 31.

Specifically, even if an interval between the adjacent gate electrodes 7 is narrowed down and an amount of the P-type impurity contained in the base region 31 between the gate electrodes 7 is reduced, a control characteristic of the gate electrodes 7 can still be stabilized because a certain threshold voltage due to the difference between the work functions qφ₁ and qφ_{P} is ensured.

Meanwhile, as shown in FIG. 7B, between the gate electrode 6 and the semiconductor layer 2, it is possible to bend the conduction band E_{C} and the valence band E_{V} downward and to form an electron accumulation region 52 on an interface between the gate insulating film 4b and the semiconductor layer 2 by setting a work function qφ₂ of the gate electrode 6 smaller than a work function qφ_{N} of the semiconductor layer 2. In this way, on-resistance of the semiconductor device 30 can be reduced.

On the other hand, even if the relation of qφ₂<qφ_{N} to achieve the band structure shown in FIG. 7B is not satisfied, the electric potential of the gate electrode 6 in a voltage amount equivalent to the difference between the work functions qφ₁ and qφ₂ can still be raised at least by setting the work function qφ₂ of the gate electrode 6 smaller than the work function qφ₁ of the gate electrode 7. In this way, it is possible to narrow down a width of the depletion region to be formed on an interface facing the gate electrode 6 between the gate insulating film 4b and the semiconductor layer 2. Moreover, the electron accumulation region 52 is easily formed in the case of applying a gate voltage. Hence the on-resistance can be reduced.

For example, when the semiconductor layer 2 has the N-type conductivity, N-type SiC is usable for the gate electrode 7 and N-type polysilicon is usable for the gate electrode 6. Alternatively, P-type polysilicon may be used for the gate electrode 7 and N-type polysilicon may be used for the gate electrode 6.

On the other hand, when the semiconductor layer 2 has the P-type conductivity, the work function of the material constituting the gate electrode 6 is set greater than the work function of the material constituting the gate electrode 7. Therefore, P-type polysilicon can be used for the gate electrode 7 and P-type or N-type SiC can be used for the gate electrode 6.

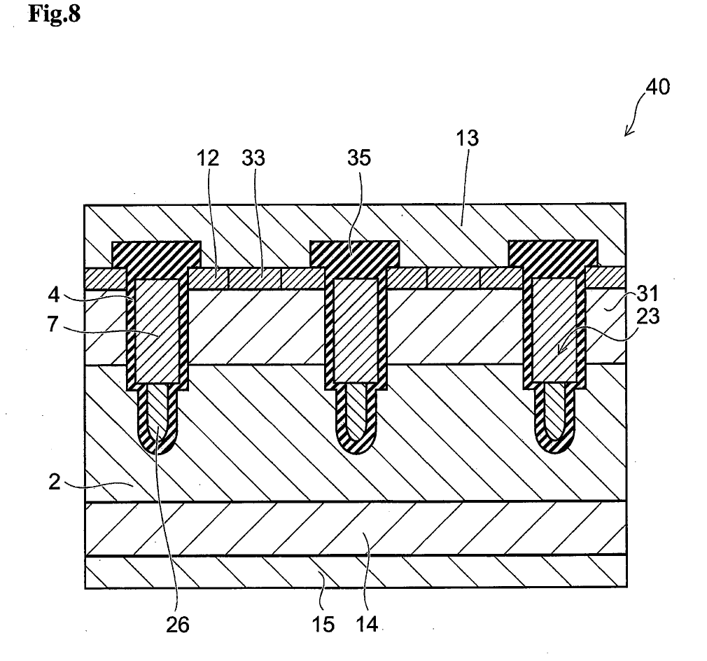

FIG. 8 is a schematic diagram showing a cross section of a semiconductor device 40 according to a modified example of the second embodiment. The semiconductor device 40 is a MOSFET including gate electrodes 7 and 26 inside trenches 23.

A bottom portion of each of the trenches 23 provided with the gate electrode 26 is formed into a narrower width than a width of an upper part of the trench 23 where the gate electrode 7 is provided. In this way, a width in an arrangement direction of the semiconductor layer 2 sandwiched between two gate electrodes 26 adjacent to each other in an arrangement direction of the trenches 23 is wider than a width in the arrangement direction of the semiconductor layer 2 sandwiched between two gate electrodes 7 adjacent to each other in the arrangement direction of the trenches 23. In this way, a wide clearance is provided for the drain current flowing from the drain electrode 15 to the source electrode 13 through a channel formed in the base region 31. Hence the on-resistance can be reduced as compared to the semiconductor device 30 shown in FIG. 6. This effect is more significant as the interval between the adjacent gate electrodes 7 is set narrower.

Moreover, as similar to the above-described semiconductor device 30, N-type SiC is usable for the gate electrode 7 and N-type polysilicon is usable for the gate electrode 6 when the semiconductor layer 2 has the N-type conductivity, for example. Alternatively, P-type polysilicon may be used for the gate electrode 7 and N-type polysilicon may be used for the gate electrode 6.

On the other hand, when the semiconductor layer 2 has the P-type conductivity, the work function of the material constituting the gate electrode 6 is set greater than the work function of the material constituting the gate electrode 7. Therefore, P-type polysilicon can be used for the gate electrode 7 and P-type or N-type SiC can be used for the gate electrode 6.

### Third Embodiment

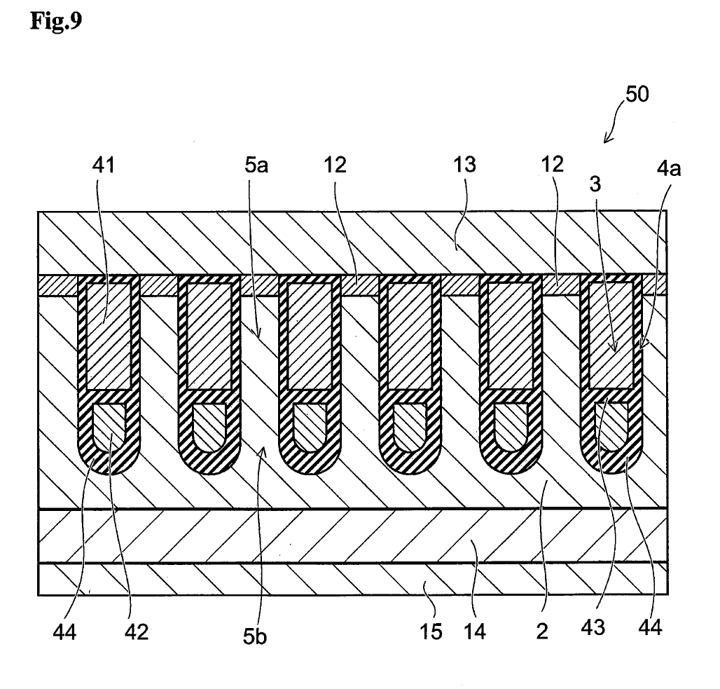

FIG. 9 is a schematic diagram showing a cross section of a semiconductor device 50 according to a third embodiment. The semiconductor device 50 includes source electrodes 42 provided at bottom portions of trenches 3, and gate electrodes 41 provided above the source electrodes 42. Each of the source electrodes 42 is insulated from each of the gate electrodes 41 by an insulating film 43. Meanwhile, each of the source electrodes 42 is electrically connected to a source electrode 13 serving as a main electrode at an unillustrated portion. The source electrode 13 is provided above the semiconductor layer 2 and is electrically connected to the semiconductor layer 2 through a source region 12.

In the semiconductor device 50 according to this embodiment, the source electrodes 42 electrically shield the gate electrodes 41 from a drain electrode 15. In this way, it is possible to make gate-drain capacitance smaller and thereby to reduce a switching loss.

Further, when the semiconductor layer 2 has the N-type conductivity, a material which has a smaller work function than that of a material constituting the gate electrodes 41 is used as a material constituting the source electrodes 42. On the other hand, when the semiconductor layer 2 has the P-type conductivity, the work function of the material constituting the source electrodes 42 is set greater than the work function of the material constituting the gate electrodes 41.

The gate electrodes 41 control widths of depletion regions extending in channel regions 5a and thereby control the drain current. Meanwhile, in channel regions 5b facing the source electrodes 42, channel resistance can be reduced by setting the depletion regions narrower than those in the channel regions 5a. Moreover, by setting a difference between the work function of the material constituting the source electrodes 42 and a work function of the semiconductor layer 2 so as to form carrier accumulation regions on interfaces between gate insulating films 4b and the semiconductor layer 2, it is possible to further reduce the channel resistance and to reduce on-resistance of the semiconductor device 50.

For example, when the semiconductor layer 2 has the N-type conductivity, P-type SiC is usable for the gate electrodes 41 and N-type SiC or polysilicon is usable for the source electrodes 42.

On the other hand, when the semiconductor layer 2 has the P-type conductivity, N-type SiC is usable for the gate electrodes 41 and P-type SiC is usable for the source electrodes 42, for example. Alternatively, N-type polysilicon may be used for the gate electrodes 41 and the P-type SiC may be used for the source electrodes 42.

In order to form the trench gates shown in FIG. 9, an insulating film 44 is formed on inner surfaces of the trenches 3 and then the trenches 3 are buried with a member constituting the source electrodes 42, for example. Subsequently, the source electrodes 42 are formed at the bottom portions of the trenches 3 by etching back the buried member. Further, after removing the insulating film 44 in spaces formed by etching back, the insulating films 43 and the insulating films constituting the gate insulating films 4a are formed. Thereafter, a member constituting the gate electrodes 41 is buried therein. In this case, it is possible to form the insulating film 44 thicker than the gate insulating film 4a in order to ensure withstand voltage between the source electrodes 42 and the drain electrode 15.

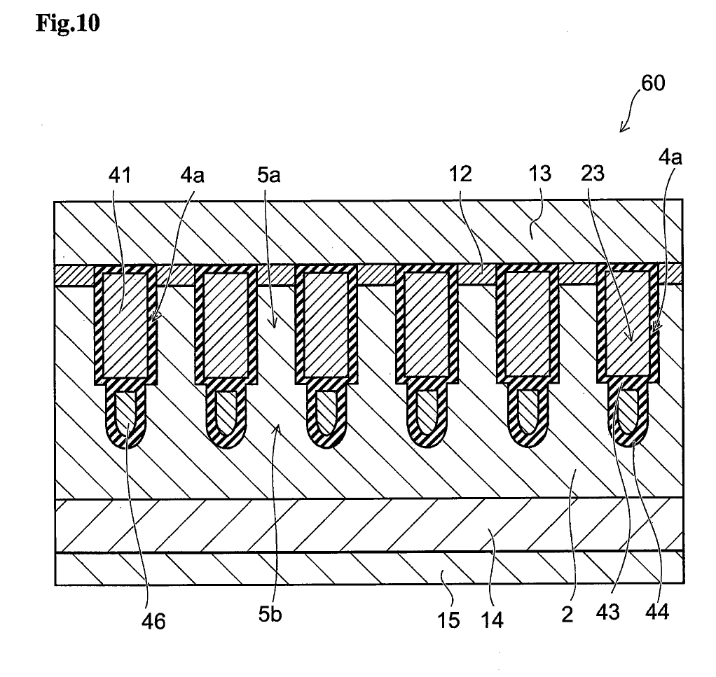

FIG. 10 is a schematic diagram showing a cross section of a semiconductor device 60 according to a modified example of the third embodiment. The semiconductor device 60 includes the gate electrodes 41 and source electrodes 46 provided inside trenches 23. Each of the gate electrodes 41 is insulated from each of the source electrodes 46 by the insulating film 43, and the source electrodes 46 are electrically connected to the source electrode 13.

A bottom portion of each of the trenches 23 provided with the source electrode 46 is formed into a narrower width than a width of an upper part of the trench 23 where the gate electrode 41 is provided. Further, a width in an arrangement direction of the trenches of each source electrode 46 provided at the bottom portion of the trench 23 is narrower than a width in the arrangement direction of each gate electrode 41. For this reason, there is a disadvantage that the gate-drain capacitance of this device is greater than that of the semiconductor device 50 shown in FIG. 9. However, it is possible to set a width of each of the channel regions 5b sandwiched between the two adjacent source electrodes 46 wider than a width of each of the channel regions 5a sandwiched between the adjacent gate electrodes 41. In this way, a wide clearance is provided for the drain current flowing from the drain electrode 15 to the source electrode 13. Hence it is possible to reduce resistance of the channel regions 5b and to reduce the on-resistance as compared to the semiconductor device 50. This effect is more significant as the channel regions 5 are set narrower.

As similar to the above-described semiconductor device 50, P-type SiC is usable for the gate electrodes 41 and N-type SiC or polysilicon is usable for the source electrode 46 when the semiconductor layer 2 has the N-type conductivity, for example.

On the other hand, when the semiconductor layer 2 has the P-type conductivity, N-type SiC is usable for the gate electrodes 41 and P-type SiC is usable for the source electrodes 46, for example. Alternatively, N-type polysilicon may be used for the gate electrodes 41 and P-type SiC may be used for the source electrodes 46.

### Fourth Embodiment

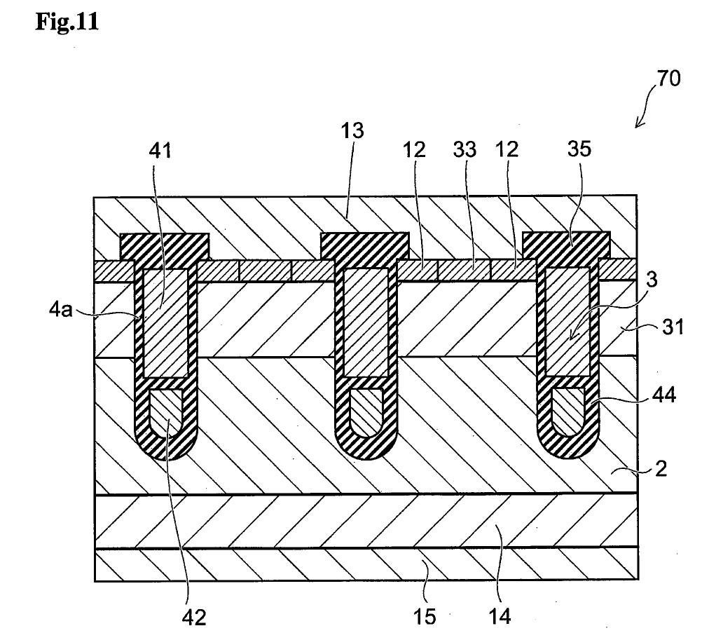

FIG. 11 is a schematic diagram showing a cross section of a semiconductor device 70 according to a fourth embodiment. The semiconductor device 70 is a MOSFET including a base region 31 provided on a surface of a semiconductor layer 2, and gate electrodes 41 and source electrodes 42 provided inside trenches 3 formed on the surface of the semiconductor layer 2.

Each of the gate electrodes 41 is insulated from each of the source electrodes 42 by an insulating film 43, and each of the source electrodes 42 is electrically connected to a source electrode 13 at an unillustrated portion. In this way, the source electrodes 42 electrically shield the gate electrodes 41 from a drain electrode 15. Hence it is possible to make gate-drain capacitance smaller. Moreover, it is possible to form insulating films 44 between the source electrodes 42 and the semiconductor layer 2 thicker than gate insulating films 4a in order to ensure withstand voltage between the source electrodes 42 and the drain electrode 15.

For example, when the semiconductor layer 2 has the N-type conductivity, it is possible to use a member which has a smaller work function than that of a member constituting the gate electrodes 41 as a member constituting the source electrodes 42. On the other hand, when the semiconductor layer 2 has the P-type conductivity, the work function of the member constituting the source electrodes 42 is set greater than the work function of the member constituting the gate electrodes 41.

In this way, it is possible to narrow down a width of a depletion region that extends from the source electrodes 42 to the semiconductor layer 2 sandwiched between the two source electrodes 42, and thereby to reduce resistance of the semiconductor layer 2. Moreover, by setting a difference between the work function of the material constituting the source electrodes 42 and a work function of the semiconductor layer 2 so as to form carrier accumulation regions on interfaces between the gate insulating films 44 and the semiconductor layer 2, it is possible to further reduce the resistance of the semiconductor layer 2 sandwiched between the source electrodes 42 and to reduce on-resistance of the semiconductor device 70.

For example, when the semiconductor layer 2 has the N-type conductivity, P-type SiC is usable for the gate electrodes 41 and N-type SiC or polysilicon is usable for the source electrodes 42.

On the other hand, when the semiconductor layer 2 has the P-type conductivity, N-type SiC is usable for the gate electrodes 41 and P-type SiC is usable for the source electrodes 42, for example. Alternatively, N-type polysilicon may be used for the gate electrodes 41 and the P-type SiC may be used for the source electrodes 42.

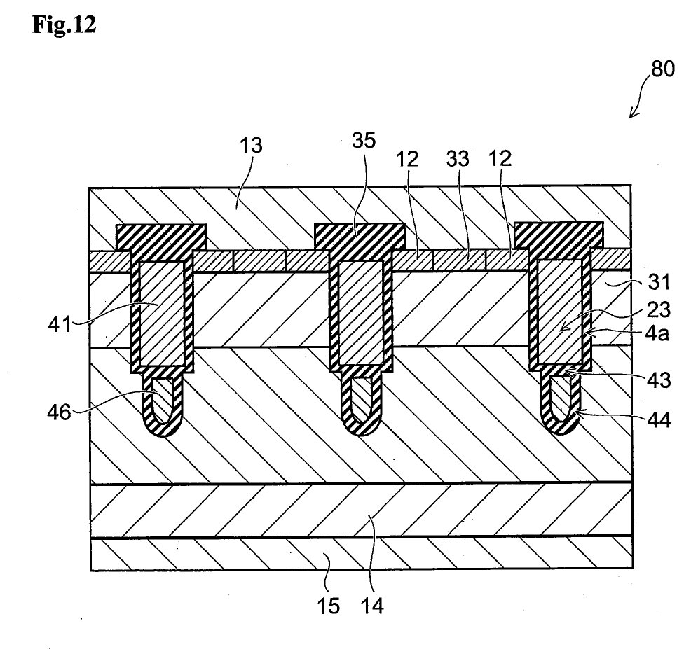

FIG. 12 is a schematic diagram showing a cross section of a semiconductor device 80 according to a modified example of the fourth embodiment. The semiconductor device 80 includes the gate electrodes 41 and source electrodes 46 provided inside trenches 23. Each of the gate electrodes 41 is insulated from each of the source electrodes 46 by the insulating film 43, and the source electrodes 46 are electrically connected to the source electrode 13.

A bottom portion of each of the trenches 23 provided with the source electrode 46 is formed into a narrower width than a width of an upper part of the trench 23 where the gate electrode 41 is provided. Accordingly, it is possible to set a width in an arrangement direction of the semiconductor layer 2 sandwiched between two source electrodes 46 adjacent to each other in an arrangement direction of the trenches wider than a width in the arrangement direction of the semiconductor layer 2 sandwiched between two adjacent gate electrodes 41. In this way, it is possible to provide a wide clearance for the drain current flowing from the drain electrode 15 to the source electrode 13 through a base region 31, and to reduce the on-resistance as compared to the semiconductor device 70 shown in FIG. 11.

This effect becomes more significant as the interval between the two adjacent gate electrodes 41 becomes narrower. Hence it may be more advantageous to reduce the on-resistance even allowing for an increase in the gate-drain capacitance due to the fact that the width in the arrangement direction of each source electrode 46 is narrower than the width in the arrangement direction of each gate electrode 41.

As similar to the above-described semiconductor device 70, P-type SiC is usable for the gate electrodes 41 and N-type SiC or polysilicon is usable for the source electrode 46 when the semiconductor layer 2 has the N-type conductivity, for example.

On the other hand, when the semiconductor layer 2 has the P-type conductivity, N-type SiC is usable for the gate electrodes 41 and P-type SiC is usable for the source electrodes 46, for example. Alternatively, N-type polysilicon may be used for the gate electrodes 41 and P-type SiC may be used for the source electrodes 46.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
an N-type semiconductor layer;
an insulating film provided on an inner surface of a trench formed on a surface of the semiconductor layer;
a first electrode provided at a bottom part of the trench and facing the semiconductor layer with the insulating film interposed therebetween; and
a second electrode provided inside the trench and above the first electrode, wherein
a work function of a member constituting the first electrode is smaller than a work function of a member constituting the second electrode.

2. The semiconductor device according to claim 1, further comprising:
a main electrode provided above the semiconductor layer and electrically connected to the semiconductor layer, wherein
the first electrode is electrically insulated from the second electrode by an insulating layer provided between the first electrode and the second electrode, and
the first electrode is electrically connected to the main electrode.

3. The semiconductor device according to claim 1, wherein
a film thickness of the insulating film provided between the semiconductor layer and the first electrode is greater than a film thickness of the insulating film provided between the semiconductor layer and the second electrode.

4. The semiconductor device according to claim 2, wherein
a film thickness of the insulating film provided between the semiconductor layer and the first electrode is greater than a film thickness of the insulating film provided between the semiconductor layer and the second electrode.

5. The semiconductor device according to claim 1, wherein
the member constituting one of the first electrode and the second electrode is a semiconductor material having N-type conductivity, and
the member constituting the other one of the first electrode and the second electrode is a semiconductor material having P-type conductivity.

6. The semiconductor device according to claim 2, wherein
the member constituting one of the first electrode and the second electrode is a semiconductor material having N-type conductivity, and
the member constituting the other one of the first electrode and the second electrode is a semiconductor material having P-type conductivity.

7. The semiconductor device according to claim 3, wherein
the member constituting one of the first electrode and the second electrode is a semiconductor material having N-type conductivity, and
the member constituting the other one of the first electrode and the second electrode is a semiconductor material having P-type conductivity.

8. The semiconductor device according to claim 1, wherein
a width, in an arrangement direction of the trenches, of the semiconductor layer interposed between the two first electrodes adjacent to each other in the arrangement direction is wider than a width, in the arrangement direction, of the semiconductor layer interposed between the two second electrodes adjacent to each other in the arrangement direction.

9. The semiconductor device according to claim 2, wherein
a width in an arrangement direction of the trenches of the semiconductor layer interposed between the two first electrodes adjacent to each other in the arrangement direction is wider than a width in the arrangement direction of the semiconductor layer interposed between the two second electrodes adjacent to each other in the arrangement direction.

10. The semiconductor device according to claim 5, wherein
a width in an arrangement direction of the trenches of the semiconductor layer interposed between the two first electrodes adjacent to each other in the arrangement direction is wider than a width in the arrangement direction of the semiconductor layer interposed between the two second electrodes adjacent to each other in the arrangement direction.

11. The semiconductor device according to claim 1, further comprising:
an N-type region provided on the surface of the semiconductor layer and doped with a higher concentration of an N-type impurity than the semiconductor layer.

12. The semiconductor device according to claim 2, further comprising:
an N-type region provided on the surface of the semiconductor layer and doped with a higher concentration of an N-type impurity than the semiconductor layer.

13. The semiconductor device according to claim 7, further comprising:
an N-type region provided on the surface of the semiconductor layer and doped with a higher concentration of an N-type impurity than the semiconductor layer.

14. The semiconductor device according to claim 1, further comprising:
a first P-type region provided on the surface of the semiconductor layer;
N-type regions provided on a surface of the first P-type region and doped with a higher concentration of an N-type impurity than the semiconductor layer; and
a second P-type region provided so as to be sandwiched between the N-type regions.

15. The semiconductor device according to claim 2, further comprising:
a first P-type region provided on the surface of the semiconductor layer;
N-type regions provided on a surface of the first P-type region and doped with a higher concentration of an N-type impurity than the semiconductor layer; and
a second P-type region provided so as to be sandwiched between the N-type regions.

16. The semiconductor device according to claim 13, further comprising:
a first P-type region provided on the surface of the semiconductor layer;
N-type regions provided on a surface of the first P-type region and doped with a higher concentration of an N-type impurity than the semiconductor layer; and
a second P-type region provided so as to be sandwiched between the N-type regions.

17. A semiconductor device comprising:
a P-type semiconductor layer;
an insulating film provided on an inner surface of a trench formed on a surface of the semiconductor layer;
a first electrode provided at a bottom part of the trench and facing the semiconductor layer with the insulating film interposed therebetween; and
a second electrode provided inside the trench and above the first electrode, wherein
a work function of a member constituting the first electrode is greater than a work function of a member constituting the second electrode.

18. The semiconductor device according to claim 17, further comprising:
a main electrode provided above the semiconductor layer and electrically connected to the semiconductor layer, wherein
the first electrode is electrically insulated from the second electrode by an insulating layer provided between the first electrode and the second electrode, and
the first electrode is electrically connected to the main electrode.

19. The semiconductor device according to claim 17, wherein
a film thickness of the insulating film provided between the semiconductor layer and the first electrode is greater than a film thickness of the insulating film provided between the semiconductor layer and the second electrode.

20. The semiconductor device according to claim 19, wherein
the member constituting one of the first electrode and the second electrode is a semiconductor material having N-type conductivity, and
the member constituting the other one of the first electrode and the second electrode is a semiconductor material having P-type conductivity.
